(19) United States
(12) Patent Application Publication
(10) Pub. No.: US 2009/0111286 A1
(43) Pub. Date: Apr. 30, 2009

(54) Wristbands incorporating electronic storage media programmed to store personal medical and identification information and methods for using same

(75) Inventor: Maria E. Giovannoni, Stockton, CA (US)

Correspondence Address: R. MICHAEL WEST;LAW OFFICES OF R. MICHAEL WEST, 1922 21ST STREET, SACRAMENTO, CA, 95811, US

(73) Assignee: My-Bands, LLC

(21) Appl. No.: 11/973,032

(22) Filed: Oct. 5, 2007

(51) Int. Cl. H01R 33/00; G11C 5/00

(52) U.S. Cl. 439/37

(57) ABSTRACT

A wristband incorporating electronic storage media programmed with accessible and downloadable personal medical and identification information. The wristband has first and second ends which are detachably coupled. An electrical connector, electrically interconnected to the storage media, extends from the first end of the wristband. Prior to use, the wristband ends are decoupled, and the electrical connector is interconnected to an external device connection port of a computer. The user responds to pre-programmed queries, to store personal information and images in the storage media. The wristband is then installed on the wrist of the user, by coupling the first and second ends. When the personal information and images must be accessed, either for use or modification, the wristband is removed and the electrical connector is interconnected to the external device connection port of any computer. The personal information and images may then be reviewed, downloaded, or modified.

### CROSS-REFERENCE TO RELATED APPLICATION

U.S. Design patent application Ser. No. 29/288,190, was filed by Applicant on Jun. 1, 2007.

### BACKGROUND OF THE INVENTION

1. Field of the Invention

The invention relates generally to the field of devices which store information about a person which can be accessed by medical and emergency personnel. More particularly, the invention pertains to a wristband incorporating electronic storage media which is user-programmed to store accessible and downloadable personal medical and identification information, and methods for using same.

2. Description of the Prior Art

Wristbands, including, for example, a person's name and a small amount of additional personal information, are well-known in the art. Such wristbands may be directly impressed with a printing or engraving of that information, or may include a telephone number or an Internet website which can be accessed for information about the person, in certain circumstances. Owing to the lack of physical space on the surface of such a wrist band, the information which can be affixed on or to the band is limited. In addition, if telephone calls or Internet access must be relied upon for more detailed information, precious time in treating the person may be lost. There are also confidentiality and accuracy problems with a system that relies upon a third-party to provide personal information to a treating physician or emergency medical personnel.

More recently, hospitals have provided patients with wrist bands including an encoded bar code pattern. At the time the patient is admitted, personnel enter patient information into computer database, and the data record is assigned a unique bar code identification. At a later time, utilizing a bar code reader connected to a hospital computer, personnel can access the patient data. While this system allows much more information to be stored and accessed, the information itself is stored in the hospital computer system and does not follow the patient after he or she leaves the hospital.

Another device currently available is a wristband containing electronic storage media, which is programmable by the wristband vendor as a service. In this arrangement, the user supplies personal information to the wristband vendor, and the vendor programs the wristband to store the user's specific personal information. Then, the programmed wristband is returned to the user. A serious disadvantage with this system, is that the user must rely upon the vendor initially to program and later update the user's information. There may be dangerous lapses of wristband availability, as the user is separated from the wristband for a period of time during the programming process. It is also inconvenient to the user, as small but important changes in information require the same return to vendor and wristband reprogramming process. For simple changes like a new phone number, a new medical prescription, a new home address, or a change of employer, the wristband would have to be returned every time to the vendor for a data update. Moreover, there are confidentiality issues with this system, as the vendor must be provided all of the user's personal information including any updates that may be provided. Personal information might be stolen or lost, and the user may then be vulnerable to misuse of the information by a third party.

### SUMMARY OF THE INVENTION

The present invention comprises a wristband incorporating electronic storage media which is user-programmed with personal information that can readily be accessed, viewed, and downloaded through the use of any computer. The programmed information may include, for example, the user's medical status and history, such as personal medication, blood type, allergies, medical records and charts, medical insurance, and particulars regarding the user's primary care physician. The programmed information may also include facts about the user's name, home address, date of birth, contact telephone numbers, emergency contact person, and employer. Image data, such as photograph, fingerprints, X-Rays, and EKG graphs, may also be programmed into the electronic storage media.

Structurally, the wristband has an elongated body including first and second ends which are detachably coupled. An electrical connector, electrically interconnected to the electronic storage media, extends from the first end of the wristband. Prior to initial use, the wristband ends are decoupled, and the electrical connector is interconnected to the external device port of a computer. The storage media in the wristband is pre-programmed with a text file, comprising a series of user queries. Once the file is accessed, the user responds to the pre-programmed queries, thereby storing personal information and personal image data in the storage media.

After programming the electronic storage media, the wristband is installed over the wrist of the user, by coupling the first and second ends. A locking mechanism extending between the first and second ends ensures that the ends will not accidentally be decoupled, resulting in possible loss of the wristband. The wristband preferably has a generally triangular configuration, and is manufactured from a resilient but pliable, silicon rubber material for comfort and durability. A digital or analog watch may be provided in the upper surface of the wristband, so the user will have the additional convenience provided by a wrist timepiece.

When the user's personal information is required to be accessed, viewed, or downloaded, the wristband is removed from the wrist of the user, and the electrical connector is interconnected the external device port of any computer. The personal information and personal image data may then be reviewed, downloaded, or modified, as necessary.

### BRIEF DESCRIPTION OF THE DRAWINGS

FIG. 1 is a perspective view of the wristband with the wristband ends coupled;

FIG. 2 is a perspective view with the wristband ends decoupled;

FIG. 3 is a perspective view showing the wristband installed on a user's wrist;

FIG. 4 is a front elevational view of the coupled wristband, showing the generally triangular configuration of the preferred embodiment;

FIG. 5 is a top plan view of a wristband including a digital watch its upper side;

FIG. 6 is a fragmentary perspective view of a laptop computer, showing the USB connector in the process of being installed in the computer's USB port, either for personal data viewing or for personal data reprogramming; and,

FIG. 7 shows the laptop computer and the wristband, electrically interconnected.

### DETAILED DESCRIPTION OF THE PREFERRED EMBODIMENT

Turning now to the drawings, personal wristband 11 includes a first end 12 detachably coupled to a second end 13. A wristband body portion 14 extends between first end 12 and second end 13. Wristband 11 is preferably generally triangular in side elevation, as shown in FIG. 4, for both comfort and attractive style. With wristband 11 so configured, first end 12 and second end 13 are effectively located in the middle portion of a leg of the triangle. Other wristband configurations, such as circular and oval may be employed, as well. It is also preferred to manufacture wristband 11 from a rubber and silicon compound, which is readily molded into the desired configuration. This material is also weather resistant, resilient, and pliable, all desirable characteristics to achieve the purposes of the present invention.

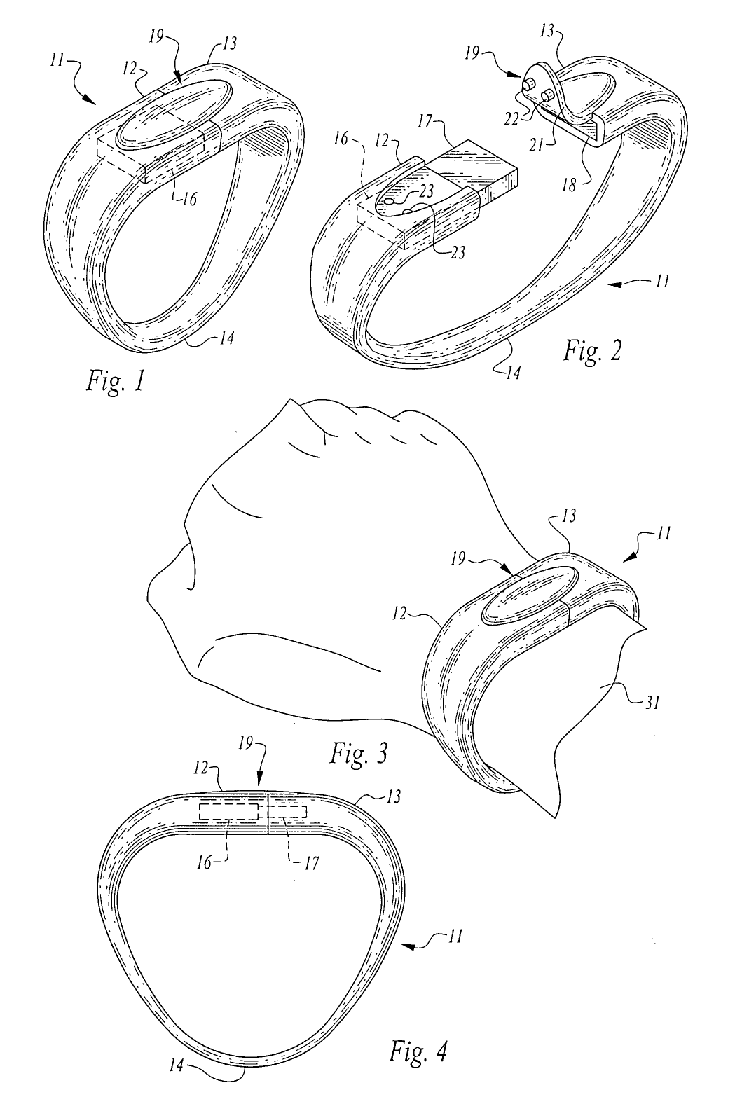

Electronic mass storage media 16, such as a flash memory card or drive, or its equivalent, is provided within the wristband 11. The particular location of storage media 16 in wristband 11 is not critical, but it may conveniently be located in first end 12, as shown in FIGS. 1 and 2. An electrical connector 17 extends from first end 12, and is electrically interconnected to storage media 16. Connector 17 is preferably a male USB (Universal Serial Bus) connector, as this connector and its operating protocols are in very common usage and are widely accepted by most computers and operating systems in current use. Connector 17 could also be located in second end 13, with obvious changes made in ends 12 and 13 to accommodate such a location reversal.

Second end 13 includes a recess 18, which is sized and configured to accept connector 17 in snug relation. First and second ends of wristband 11 are thereby coupled together by inserting connector 17 into recess 18. Recess 18 also provides a degree of protection from the elements, for the electrical contacts within connector 17. This protection is such that the wristband 11 is generally weather proof, and with reasonable care, will be impervious to rain, dust, and shock forces.

Locking means 19 is provided to prevent the first and second ends of the wristband from accidentally decoupling, during physical activity of the user. Locking means 19 comprises a flexible flap 21 extending from second end 13, as shown in FIG. 2. Flexible flap 21 is provided with at least one protruding nub 22, on its lower side. Locking means 19 also includes at least one corresponding nub receiver 23, on first end 12. Other structurally equivalent means may be provided to maintain the first and second ends of the wristband in coupled relation. For example, a ball and detent arrangement, either separate from or integrated with connector 17, would function in acceptable fashion. Or barbs, prongs, or other locking members extending between the two ends into a receiver would function to prevent accidental decoupling, equally well.

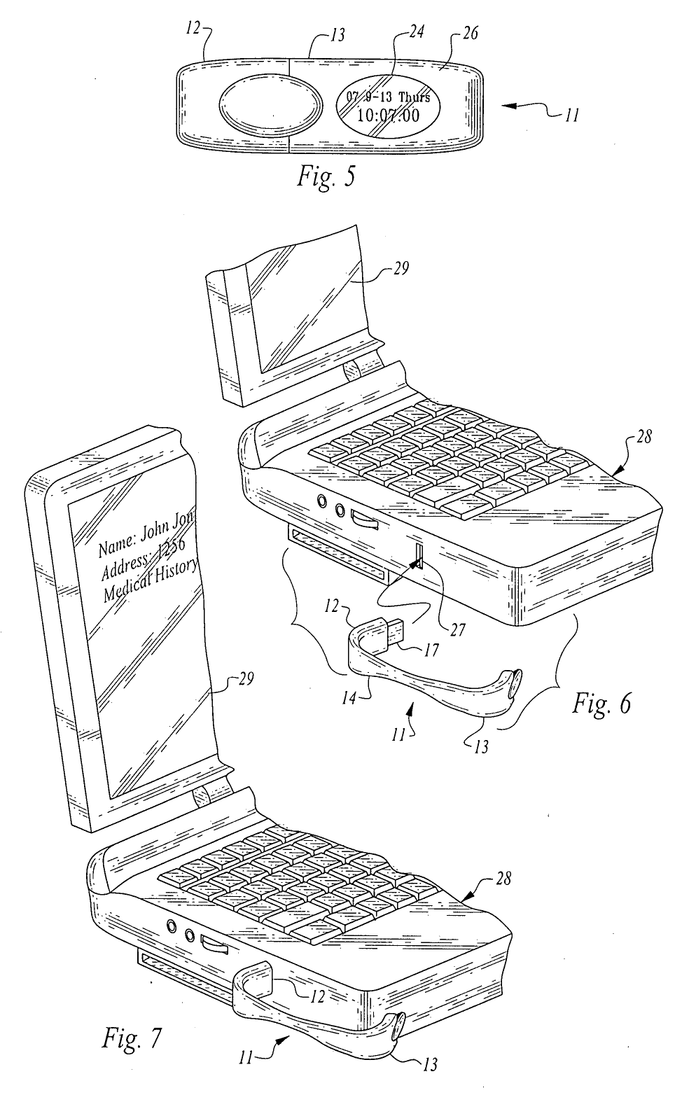

As shown in FIG. 5, an alternative embodiment of the wristband 11 may include a digital or analog watch 24, embedded within the upper facing side 26 of the wristband. This feature is desirable for those users who do not want to have both a watch and a separate wristband on their wrist. Integrating a watch with the electronic storage feature of the wristband allows the user to have the convenience and safety of both features in the same package. Watch 24 may be located either on second end 13, or first end 12, depending upon the selected location for storage media 16 and electrical connector 17. In other words, these components may be arranged as desired in the wristband, as there is no criticality to their location.

Prior to its initial use by the user, the wristband 11 must be programmed with the user's personal information, including personal image data, if desired. For that purpose, the first and second ends of the wristband are decoupled, and the electrical connector 17 is plugged into the external device port 27 of computer 28. Typically and preferably, port 27 will be the common and ubiquitous USB female port found on most modern computers.

The electronic storage media 16 has been pre-programmed with a text file, comprising a series of queries designed to elicit important personal information from the user. A text, or “TXT” file, was selected for the pre-programmed queries, so that the wristband will have widespread adaptability to different computers with different operating systems and different word processing software. In other words, by plugging the electrical connector 17 into the USB port of a computer 28, the pre-programmed text file in the wristband media will be readable and usable with just about every personal computer currently in use.

The following represents a sample of the pre-programmed queries which will first come up on the screen 29 of computer 28, when the wristband is first plugged into the port 27 and accessed by the computer's operating system.

As is evident, these queries are particularly directed toward collecting medical information, personal contact information, and identification data from the user. However, these queries can easily be modified, expanded, or restricted as necessary, to meet the needs of the user.

An important feature of the wristband 11, is that the personal information stored is readily accessible and programmable by the user, not only for initial programming, but for any subsequent changes and additions in programming which need to be made. If the user of the wristband 11 moves to a new residence or changes their cell phone number, that information can be updated and changed by the user in minutes. If the user has a change in their medication, that information can be inputted into the electronic storage media 16 by simply plugging the connector 17 into any available computer. If a person has a new hair style or color, or a child has changed in appearance as time passes, the photograph of the user can easily be updated by the user or a parent of the user by opening a stored file containing that new image, and saving it in the TXT file in the storage media 16.

After the storage media 16 in the wristband 11 has been programmed by the user, the wristband is then installed on the wrist 31 of the user, by coupling first end 12 and second end 13. Locking means 19 is then engaged, by pressing flexible flap 21 against first end 12 so that nubs 22 snugly enter nub receivers 23.

When personal information must be accessed, the wristband 11 is removed from the user, and the electrical connector 17 is interconnected to the external device connection port 27 of any computer. For example, if the user is unconscious or incapacitated, emergency personnel can readily remove the wristband 11 from the user and interconnect the wristband's connector 17 to a field or office computer. Gaining access to and viewing the medical information about the user will enable emergency personnel or an attending physician in providing the most effective and safest treatment to the user. Similarly, if the user is a lost child, a police officer or other security personnel can remove the wristband from the child, interconnect the wristband to a computer at hand, and access personal identification and contact information about the child. The photograph and fingerprint information can be cross-checked with the child to confirm identity, and perhaps cross-checked with other data bases available to the officer, as well. If necessary, the information can be downloaded and saved on the accessing computer, and the file can be forwarded to others as necessary using existing computer networks.

It will be appreciated, then, that I have disclosed a wristband incorporating electronic storage media which is pre-programmed with queries, so that the user can conveniently and quickly program the wristband to store accessible and downloadable personal medical and identification information and associated images.

What is claimed is:

1. A personal wristband incorporating electronic storage media, comprising:
a. a wristband having a first end and a second end, said first end and said second end being detachably coupled;
b. electronic storage media within said wristband, said electronic storage media being programmed to store personal information; and,
c. an electrical connector extending from said first end of said wristband, said electrical connector being electrically interconnected to said storage media, whereby said personal information is downloadable to a computer by decoupling said first end from said second end and interconnecting said electrical connector to the computer.

2. A wristband as in claim 1 in which said second end includes a recess and in which said electrical connector extends into said recess when said first end and said second end are coupled.

3. A wristband as in claim 1 in which said electrical connector is a male USB connector.

4. A wristband as in claim 1 in which said wristband is made from a resilient and pliant material.

5. A wristband as in claim 4 in which said wristband is generally configured in the shape of a triangle, and in which said first end and said second end are located in the middle portion of a leg of the triangle.

6. A wristband as in claim 1 including locking means extending between said first and second ends for maintaining said first and second ends in coupled relation.

7. A wristband as in claim 6 in which said locking means comprises a flexible flap extending from said second end, said flexible flap being provided with at least one protruding nub on its lower side, and in which said first end includes a nub receiver.

8. A wristband as in claim 1 in which said electronic storage media is pre-programmed with a series of queries regarding personal information to be programmed and stored.

9. A wristband as in claim 1 in which said queries include questions about an individual's medical history, prescriptions, and contact information.

10. A personal wristband incorporating electronic storage media, comprising:
a. a wristband having a first end and a second end, said first end and said second end being detachably coupled;
b. electronic storage media within said wristband;
c. an electrical connector extending from said first end of said wristband, said electrical connector being electrically interconnected to said storage media and insertable into said second end for coupling said first and second ends, whereby said first end and said second end are decoupled, said electrical connector is interconnected to a computer, and said electronic storage media is programmed to store personal information.

11. A wristband as in claim 10 in which said second end includes a recess and in which said electrical connector extends into said recess when said first end and said second end are coupled.

12. A wristband as in claim 10 in which said electrical connector is a male USB connector.

13. A wristband as in claim 10 in which said wristband is made from a resilient and pliant material.

14. A wristband as in claim 13 in which said wristband is generally configured in the shape of a triangle, and in which said first end and said second end are located in the middle portion of a leg of the triangle.

15. A wristband as in claim 10 including locking means extending between said first and second ends for maintaining said first and second ends in coupled relation.

16. A wristband as in claim 15 in which said locking means comprises a flexible flap extending from said second end, said flexible flap being provided with at least one protruding nub on its lower side, and in which said first end includes a nub receiver.

17. A wristband as in claim 10 in which said electronic storage media is pre-programmed with a series of queries regarding personal information to be programmed and stored.

18. A wristband as in claim 17 in which said queries include questions about an individual's medical history, prescriptions, and contact information.

19. A method for using a personal wristband incorporating electronic storage media, comprising:
a. providing a wristband having a first end and a second end, said first end and said second end being detachably coupled, said wristband including electronic storage media therein;
b. providing an electrical connector which extends from said first end of said wristband, said electrical connector being electrically interconnected to said storage media;
c. decoupling said first end from said second end of said wristband;
d. interconnecting a computer to said electrical connector;
e. programming said electronic storage media with an individual's personal information;
f. placing said wristband around said individual's wrist, and coupling said first end to said second end.

20. A method as in claim 19, further including the steps of:
g. decoupling said first end from said second end;
h. interconnecting a computer to said electrical connector; and,
i. downloading said personal information to the computer.
